(19) United States
(12) Patent Application Publication
(10) Pub. No.: US 2026/0158661 A1
(43) Pub. Date: Jun. 11, 2026

(54) WAFER HANDLING APPARATUS AND METHOD FOR MONITORING WAFER HANDLING APPARATUS

(71) Applicant: NANYA TECHNOLOGY CORPORATION, New Taipei City (TW)

(72) Inventor: Yi-Wen LIU, New Taipei City (TW)

(21) Appl. No.: 18/976,259

(22) Filed: Dec. 10, 2024

(51) Int. Cl. B25J 9/16; B25J 11/00; B25J 13/08; H01L 21/677; H01L 21/68; H01L 21/687

(52) U.S. Cl. CPC B25J 9/1694; B25J 11/0095; B25J 13/08; H10P 72/3411; H10P 72/50; H10P 72/7602

(57) ABSTRACT

A wafer handling apparatus includes a housing, a load port, a robotic arm, a sensor group and a processing unit. The load port is mounted on a side of the housing and configured to receive a wafer container which accommodates at least one wafer. The robotic arm is disposed inside the housing and configured to transfer the wafer into or out of the wafer container. The robotic arm includes a handling portion and a moving portion. The handling portion is configured to hold the wafer. The moving portion is connected with the handling portion and configured to move the handling portion relative to the load port. The sensor group is disposed on the load port. The sensor group includes at least one first sensor configured to obtain a first height level of the handling portion. The processing unit is signally connected with the sensor group.

### BACKGROUND

### Technical Field

The present disclosure relates to wafer handling apparatus and methods for monitoring a wafer handling apparatus.

### Description of Related Art

Since the living standards have been rising nowadays, electronic products are becoming more and more important in our daily lives. Facing to the huge market of electronic products, various manufacturers are working hard to enhance the market competitiveness of their brands.

In fact, apart from strengthening research and development on the functions and performances of electronic products, how to effectively improve the operational efficiency in the production process of electronic products, thereby reducing the production costs of electronic products, is undoubtedly an important issue that various manufacturers highly concern.

### SUMMARY

A technical aspect of the present disclosure is to provide a wafer handling apparatus, which can effectively reduce the possibility to damage of the semiconductor wafer by the handling portion of the robotic arm during movement.

According to an embodiment of the present disclosure, a wafer handling apparatus includes a housing, a load port, a robotic arm, a first sensor group and a processing unit. The load port is mounted on a side of the housing and configured to receive a wafer container. The wafer container is configured to accommodate at least one semiconductor wafer. The robotic arm is disposed inside the housing and configured to transfer the semiconductor wafer into or out of the wafer container. The robotic arm includes a handling portion and a moving portion. The handling portion is configured to hold the semiconductor wafer. The moving portion is connected with the handling portion and configured to move the handling portion relative to the load port. The first sensor group is disposed on the load port. The first sensor group includes at least one first sensor. The first sensor is configured to obtain a first height level of the handling portion. The processing unit is signally connected with the first sensor group.

In one or more embodiments of the present disclosure, the first sensor is configured to measure a first distance from the handling portion.

In one or more embodiments of the present disclosure, the first sensor group includes at least one second sensor. The second sensor is configured to obtain a first orientation level of the handling portion.

In one or more embodiments of the present disclosure, the second sensor includes at least two first subsidiary sensors. Each of the first subsidiary sensors is configured to measure a second distance from the handling portion. The processing unit is configured to calculate a first inclination angle of the handling portion according to a first difference between the second distances measured.

In one or more embodiments of the present disclosure, the first subsidiary sensors are spaced apart from each other and are disposed on a same horizontal level.

In one or more embodiments of the present disclosure, the wafer handling apparatus further includes a second sensor group. The second sensor group is disposed inside the housing away from the load port and signally connected with the processing unit. The second sensor group includes at least one third sensor. The third sensor is configured to obtain a second height level of the handling portion.

In one or more embodiments of the present disclosure, the third sensor is configured to measure a third distance from the handling portion.

In one or more embodiments of the present disclosure, the second sensor group further includes at least one fourth sensor. The fourth sensor is configured to obtain a second orientation level of the handling portion.

In one or more embodiments of the present disclosure, the fourth sensor includes at least two second subsidiary sensors. Each of the second subsidiary sensors is configured to measure a fourth distance from the handling portion. The processing unit is configured to calculate a second inclination angle of the handling portion according to a second difference between the fourth distances measured.

In one or more embodiments of the present disclosure, the second subsidiary sensors are spaced apart from each other and are disposed on a same horizontal level.

A technical aspect of the present disclosure is to provide a method for monitoring a wafer handling apparatus, which can effectively reduce the possibility to damage of the semiconductor wafer by the handling portion of the robotic arm during movement.

According to an embodiment of the present disclosure, a method for monitoring a wafer handling apparatus is provided. The method includes: providing a first sensor group on a load port mounted on a side of a housing of the wafer handling apparatus, in which the load port is configured to receive a wafer container, the wafer container is configured to accommodate at least one semiconductor wafer, the housing is configured to accommodate a robotic arm for moving the semiconductor wafer into or out of the wafer container, the robotic arm includes a handling portion and a moving portion, the handling portion is configured to hold the semiconductor wafer, and the moving portion is connected with the handling portion and configured to move the handling portion relative to the load port; obtaining a first height level of the handling portion by the first sensor group; receiving a first signal from the first sensor group; and analyzing the first signal and determining if the first height level obtained is within a first predetermined range.

In one or more embodiments of the present disclosure, the first sensor group measures a first vertical distance from the handling portion.

In one or more embodiments of the present disclosure, the method further includes: obtaining a first orientation level of the handling portion by the first sensor group; receiving a second signal from the first sensor group; and analyzing the second signal and determining if the first orientation level obtained is within a second predetermined range.

In one or more embodiments of the present disclosure, obtaining the first orientation level includes measuring at least two second vertical distances from the handling portion. Analyzing the second signal includes: calculating a first inclination angle of the handling portion according to a first difference between the second vertical distances measured.

In one or more embodiments of the present disclosure, the method further includes: defining a reference zone inside the housing away from the load port; providing a second sensor group within the reference zone; moving the handling portion to the reference zone; obtaining a second height level of the handling portion by the second sensor group; receiving a third signal from the second sensor group; and. analyzing the third signal and determining if the second height level obtained is within a third predetermined range.

In one or more embodiments of the present disclosure, the second sensor group measures a third vertical distance from the handling portion.

In one or more embodiments of the present disclosure, the method further includes: obtaining a second orientation level of the handling portion by the second sensor group; receiving a fourth signal from the second sensor group; and analyzing the fourth signal and determining if the second orientation level obtained is within a fourth predetermined range.

In one or more embodiments of the present disclosure, obtaining the second orientation level includes: measuring at least two fourth vertical distances from the handling portion. Analyzing the fourth signal includes: calculating a second inclination angle of the handling portion according to a second difference between the fourth vertical distances measured.

In one or more embodiments of the present disclosure, the first sensor group includes a plurality of first distance sensors and the second sensor group includes a plurality of second distance sensors. A first position arrangement of the first distance sensors is same as a second position arrangement of the second distance sensors.

The above-mentioned embodiments of the present disclosure have at least the following advantages:
(1) Since both the vertical and the horizontal level of the handling portion of the robotic arm are monitored, the possibility to damage of the semiconductor wafer by the handling portion during movement is effectively reduced.
(2) Since the proper functioning of the first sensor group at the load port can be verified by the second sensor group at the reference zone, the possibility to damage of the semiconductor wafer by the handling portion of the robotic arm during movement is effectively reduced.

### BRIEF DESCRIPTION OF THE DRAWINGS

The disclosure can be more fully understood by reading the following detailed description of the embodiments, with reference made to the accompanying drawings as follows:

FIG. 1 is a sectional side view of a wafer handling apparatus according to an embodiment of the present disclosure;

FIG. 2 is a sectional view along a sectional line A-A of FIG. 1;

FIG. 3 is a top view of the wafer handling apparatus of FIG. 1;

FIG. 4 is a sectional view along a sectional line B-B of FIG. 3; and

FIG. 5 is a flow diagram of a method for monitoring a wafer handling apparatus according to an embodiment of the present disclosure.

### DETAILED DESCRIPTION

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

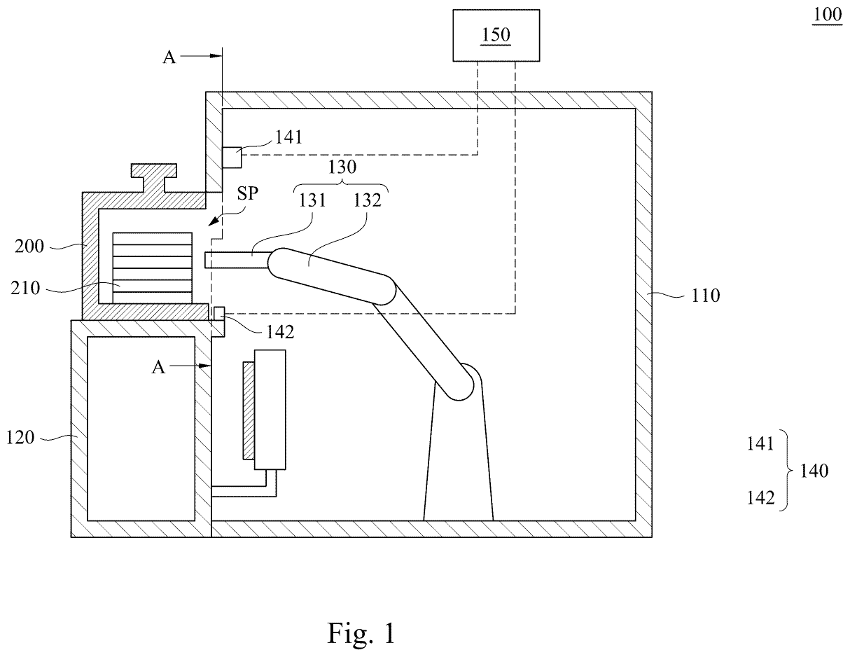

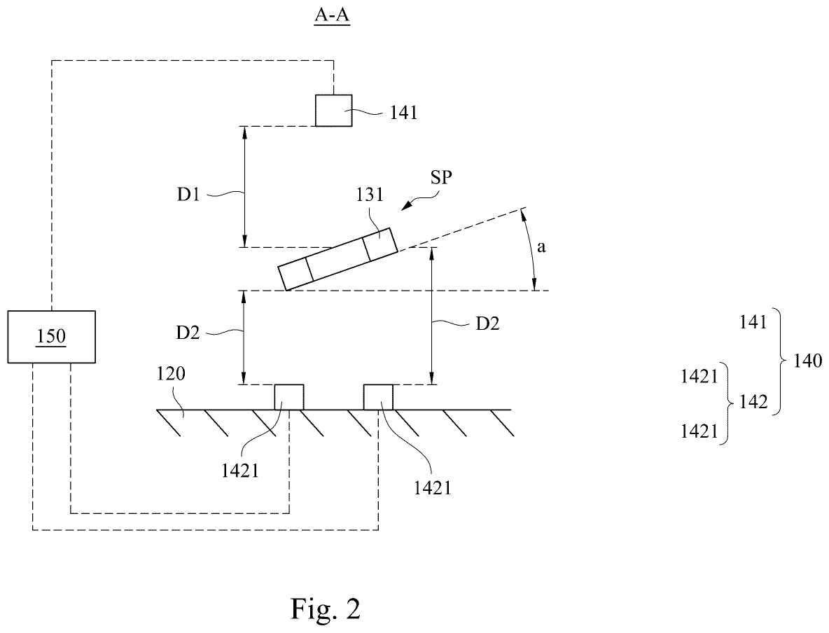

Reference is made to FIGS. 1-2. FIG. 1 is a sectional side view of a wafer handling apparatus 100 according to an embodiment of the present disclosure. FIG. 2 is a sectional view along a sectional line A-A of FIG. 1. In this embodiment, as shown in FIGS. 1-2, a wafer handling apparatus 100 includes a housing 110, a load port 120, a robotic arm 130, a first sensor group 140 and a processing unit 150. The load port 120 is mounted on a side of the housing 110 and configured to receive a wafer container 200. The wafer container 200 is configured to accommodate at least one semiconductor wafer 210. The robotic arm 130 is disposed inside the housing 110 and configured to transfer the semiconductor wafer 210 into or out of the wafer container 200. The robotic arm 130 includes a handling portion 131 and a moving portion 132. The handling portion 131 is configured to hold the semiconductor wafer 210. The moving portion 132 is connected with the handling portion 131 and configured to move the handling portion 131 and thus the semiconductor wafer 210 relative to the load port 120. The first sensor group 140 is disposed on the load port 120. The processing unit 150 is signally connected with the first sensor group 140. The first sensor group 140 includes at least one first sensor 141 and at least one second sensor 142. The first sensor 141 is configured to obtain a first height level of the handling portion 131 while the second sensor 142 is configured to obtain a first orientation level of the handling portion 131. For example, as shown in FIGS. 1-2, the first sensor 141 and the second sensor 142 define a space SP therebetween, such that the handling portion 131 of the robotic arm 130 can pass through to access the wafer container 200. At this point, as shown in FIGS. 1-2, when the handling portion 131 is moved to access the wafer container 200, the first sensor 141 and the second sensor 142 are located in opposite sides of the handling portion 131. In other embodiments, according to the actual situation, the first sensor 141 and the second sensor 142 can be located at the same side relative to the handling portion 131.

To be specific, as shown in FIG. 2, the first sensor 141 is configured to measure a first distance D1 vertically from the handling portion 131. In practical applications, after the position calibration of the robotic arm 130 is completed, the first sensor 141 then measures the first distance D1 from the handling portion 131 to generate a reference of first distance D1. Afterwards, when the robotic arm 130 is used to transfer the semiconductor wafer 210 into or out of the wafer container 200, the first sensor 141 will measure the first distance D1 from the handling portion 131 and sends a first signal to the processing unit 150 for analysis. In case the first distance D1 measured exceeds the reference of first distance D1 by a first predetermined range as analyzed by the processing unit 150, an alarm may be activated to draw an attention from the user. Furthermore, in case the first distance D1 measured has exceeded the first predetermined range further by a certain extent as analyzed by the processing unit 150, the operation of the wafer handling apparatus 100 may be instantly stopped for safety considerations. In this way, the vertical level of the handling portion 131 is monitored, and the possibility to damage of the semiconductor wafer 210 by the handling portion 131 of the robotic arm 130 during movement is effectively reduced.

Furthermore, as shown in FIG. 2, the second sensor 142 includes at least two first subsidiary sensors 1421. Each of the first subsidiary sensors 1421 is configured to measure a second distance D2 vertically from the handling portion 131. The processing unit 150 is configured to calculate a first inclination angle a of the handling portion 131 according to a first difference between the second distances D2 measured. In practical applications, similarly, after the position calibration of the robotic arm 130 is completed, the first subsidiary sensors 1421 are used to measure the second distances D2 from the handling portion 131. The processing unit 150 then calculates a first inclination angle a from the first difference between the second distances D2 measured and generates a reference of first inclination angle a. Afterwards, when the robotic arm 130 is used to transfer the semiconductor wafer 210 into or out of the wafer container 200, the first subsidiary sensors 1421 of the second sensor 142 will measure the second distances D2 from the handling portion 131 and send a second signal to the processing unit 150 for analysis. In case the first inclination angle a calculated from the second distances D2 measured exceeds the reference of first inclination angle a by a second predetermined range as analyzed by the processing unit 150, an alarm may be activated to draw an attention from the user. Furthermore, in case the first inclination angle a calculated has exceeded the second predetermined range further by a certain extent as analyzed by the processing unit 150, the operation of the wafer handling apparatus 100 may be instantly stopped for safety considerations. In this way, the horizontal level of the handling portion 131 is monitored, and the possibility to damage of the semiconductor wafer 210 by the handling portion 131 of the robotic arm 130 during movement is effectively reduced.

For a better accuracy to calculate the first inclination angle a, as shown in FIG. 2, the first subsidiary sensors 1421 are spaced apart from each other and are disposed on a same horizontal level.

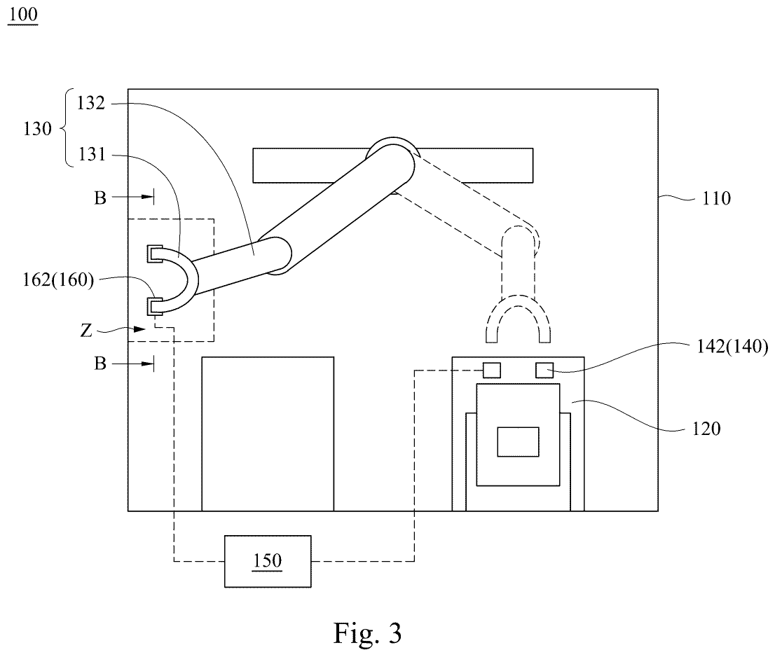

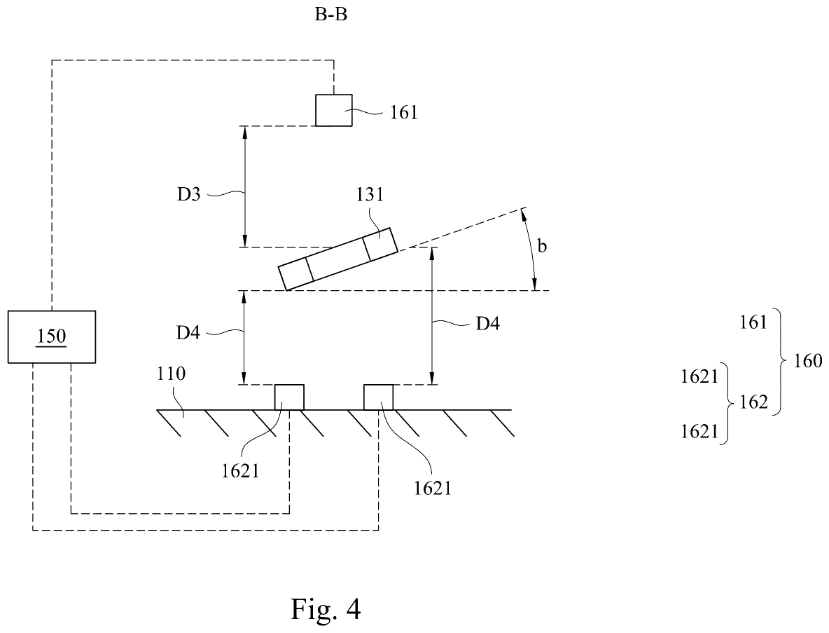

Reference is made to FIGS. 3-4. FIG. 3 is a top view of the wafer handling apparatus 100 of FIG. 1. FIG. 4 is a sectional view along a sectional line B-B of FIG. 3. In this embodiment, as shown in FIGS. 3-4, the housing 110 defines a reference zone Z therein and the reference zone Z is away from the load port 120. Moreover, the wafer handling apparatus 100 further includes a second sensor group 160. The second sensor group 160 is located in the reference zone Z and signally connected with the processing unit 150. The second sensor group 160 includes at least one third sensor 161 and at least one fourth sensor 162. The third sensor 161 is configured to obtain a second height level of the handling portion 131 while the fourth sensor 162 is configured to obtain a second orientation level of the handling portion 131. For the sake of drawing simplification, the first sensor 141 and the third sensor 161 are not shown in FIG. 3. In practical applications, after a certain times or a certain period of time of usages of the robotic arm 130 to transfer the semiconductor wafer 210 into or out of the wafer container 200, the robotic arm 130 can drive the handling portion 131 to the reference zone Z for checking its height level and orientation level by the second sensor group 160, so as to verify the proper functioning of the first sensor group 140 at the load port 120. For example, as shown in FIG. 3, the handling portion 131 is moved from the position drawn in hidden lines to the position drawn in solid lines, which is at least partially located in the reference zone Z.

To be specific, as shown in FIG. 4, the third sensor 161 is configured to measure a third distance D3 vertically from the handling portion 131. In practical applications, after the reference of first distance D1 is obtained by the first sensor 141 of the first sensor group 140, the handling portion 131 of the robotic arm 130 is driven to the reference zone Z, and the third sensor 161 then measures the third distance D3 from the handling portion 131 to generate a reference of third distance D3. Afterwards, after a certain times or a certain period of time of usages of the robotic arm 130 to transfer the semiconductor wafer 210 into or out of the wafer container 200, the robotic arm 130 then drives the handling portion 131 to the reference zone Z, and the third sensor 161 will measure the third distance D3 from the handling portion 131 and sends a third signal to the processing unit 150 for analysis. In case the third distance D3 measured exceeds the reference of third distance D3 by a third predetermined range as analyzed by the processing unit 150, an alarm may be activated to draw an attention from the user. Furthermore, in case the third distance D3 measured has exceeded the third predetermined range further by a certain extent as analyzed by the processing unit 150, the operation of the wafer handling apparatus 100 may be instantly stopped for safety considerations. In this way, the proper functioning of the first sensor 141 of the first sensor group 140 is verified, and the possibility to damage of the semiconductor wafer 210 by the handling portion 131 of the robotic arm 130 during movement is effectively reduced.

Furthermore, as shown in FIG. 4, the fourth sensor 162 includes at least two second subsidiary sensors 1621. Each of the second subsidiary sensors 1621 is configured to measure a fourth distance D4 vertically from the handling portion 131. The processing unit 150 is configured to calculate a second inclination angle b of the handling portion 131 according to a second difference between the fourth distances D4 measured. In practical applications, similarly, after the reference of first inclination angle a is obtained by the second sensor 142 of the first sensor group 140, the handling portion 131 of the robotic arm 130 is driven to the reference zone Z, and the second subsidiary sensors 1621 then measure the fourth distances D4 from the handling portion 131. The processing unit 150 then calculates a second inclination angle b from the second difference between the fourth distances D4 measured and generates a reference of second inclination angle b. Afterwards, after a certain times or a certain period of time of usages of the robotic arm 130 to transfer the semiconductor wafer 210 into or out of the wafer container 200, the robotic arm 130 then drives the handling portion 131 to the reference zone Z, and the second subsidiary sensors 1621 of the fourth sensor 162 will measure the fourth distances D4 from the handling portion 131 and send a fourth signal to the processing unit 150 for analysis. In case the second inclination angle b calculated from the fourth distances D4 measured exceeds the reference of second inclination angle b by a fourth predetermined range as analyzed by the processing unit 150, an alarm may be activated to draw an attention from the user. Furthermore, in case the second inclination angle b calculated has exceeded the fourth predetermined range further by a certain extent as analyzed by the processing unit 150, the operation of the wafer handling apparatus 100 may be instantly stopped for safety considerations. In this way, the proper functioning of the second sensor 142 of the first sensor group 140 is verified, and the possibility to damage of the semiconductor wafer 210 by the handling portion 131 of the robotic arm 130 during movement is effectively reduced.

Similarly, for a better accuracy to calculate the second inclination angle b, as shown in FIG. 4, the second subsidiary sensors 1621 are spaced apart from each other and are disposed on a same horizontal level.

In addition, in order to achieve a more accurate verification by the second sensor group 160 to the first sensor group 140, as shown in FIG. 2 and FIG. 4, the position arrangement of the first sensor 141 and the first subsidiary sensors 1421 of the second sensor 142 is the same as the position arrangement of the third sensor 161 and the second subsidiary sensors 1621 of the fourth sensor 162.

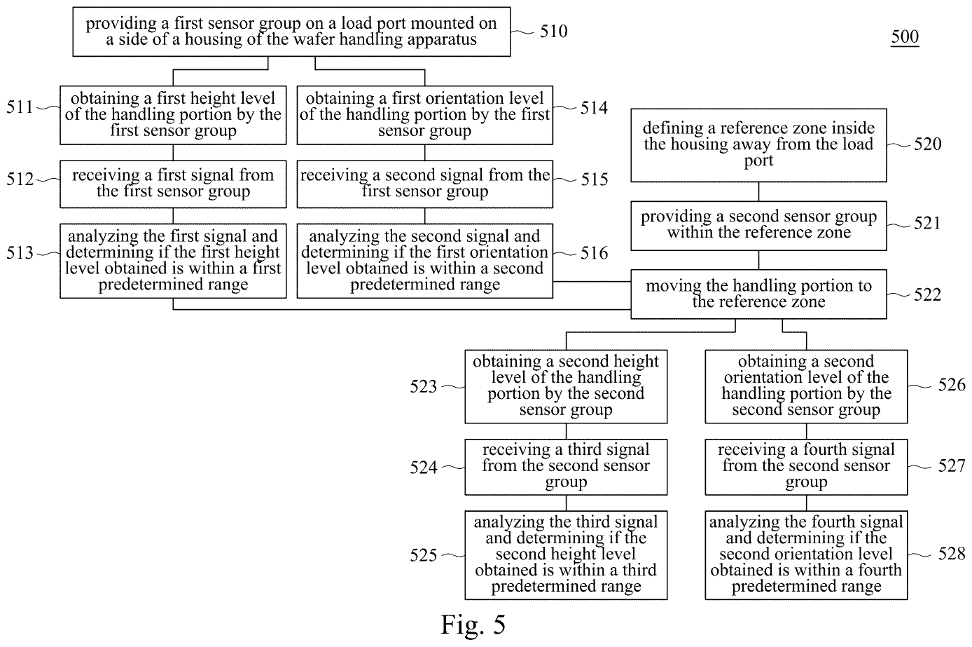

Reference is made to FIG. 5. FIG. 5 is a flow diagram of a method 500 for monitoring a wafer handling apparatus according to an embodiment of the present disclosure. Apart from the wafer handling apparatus as mentioned above, another aspect of the present disclosure provides a method 500 of monitoring a wafer handling apparatus. As shown in FIG. 5, the method 500 of monitoring a wafer handling apparatus includes the following procedures, which should be understood that the order of procedures mentioned below can be changed as per actual requirements, and some of the procedures may be executed simultaneously or partially simultaneously unless their sequence is explicitly stated:
Procedure 510: providing a first sensor group 140 on a load port 120 mounted on a side of a housing 110 of the wafer handling apparatus 100.
Procedure 511: obtaining a first height level of the handling portion 131 by the first sensor group 140.
Procedure 512: receiving a first signal from the first sensor group 140.
Procedure 513: analyzing the first signal and determining if the first height level obtained is within a first predetermined range.
Procedure 514: obtaining a first orientation level of the handling portion 131 by the first sensor group 140.
Procedure 515: receiving a second signal from the first sensor group 140.
Procedure 516: analyzing the second signal and determining if the first orientation level obtained is within a second predetermined range.
Procedure 520: defining a reference zone Z inside the housing 110 away from the load port 120.
Procedure 521: providing a second sensor group 160 within the reference zone Z.
Procedure 522: moving the handling portion 131 to the reference zone Z.
Procedure 523: obtaining a second height level of the handling portion 131 by the second sensor group 160.
Procedure 524: receiving a third signal from the second sensor group 160.
Procedure 525: analyzing the third signal and determining if the second height level obtained is within a third predetermined range.
Procedure 526: obtaining a second orientation level of the handling portion 131 by the second sensor group 160.
Procedure 527: receiving a fourth signal from the second sensor group 160.
Procedure 528: analyzing the fourth signal and determining if the second orientation level obtained is within a fourth predetermined range.

In conclusion, the aforementioned embodiments of the present disclosure have at least the following advantages:
(1) Since both the vertical and the horizontal level of the handling portion of the robotic arm are monitored, the possibility to damage of the semiconductor wafer by the handling portion during movement is effectively reduced.
(2) Since the proper functioning of the first sensor group at the load port can be verified by the second sensor group at the reference zone, the possibility to damage of the semiconductor wafer by the handling portion of the robotic arm during movement is effectively reduced.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. A wafer handling apparatus, comprising:
a housing;
a load port mounted on a side of the housing and configured to receive a wafer container, the wafer container being configured to accommodate at least one semiconductor wafer;
a robotic arm disposed inside the housing and configured to transfer the semiconductor wafer into or out of the wafer container, the robotic arm comprising:
a handling portion configured to hold the semiconductor wafer; and
a moving portion connected with the handling portion and configured to move the handling portion relative to the load port;
a first sensor group disposed on the load port, the first sensor group comprising:
at least one first sensor configured to obtain a first height level of the handling portion; and
a processing unit signally connected with the first sensor group.

2. The wafer handling apparatus of claim 1, wherein the first sensor is configured to measure a first distance from the handling portion.

3. The wafer handling apparatus of claim 1, wherein the first sensor group comprises:
at least one second sensor configured to obtain a first orientation level of the handling portion.

4. The wafer handling apparatus of claim 3, wherein the second sensor comprises at least two first subsidiary sensors, each of the first subsidiary sensors is configured to measure a second distance from the handling portion, the processing unit is configured to calculate a first inclination angle of the handling portion according to a first difference between the second distances measured.

5. The wafer handling apparatus of claim 4, wherein the first subsidiary sensors are spaced apart from each other and are disposed on a same horizontal level.

6. The wafer handling apparatus of claim 1, further comprising:
a second sensor group disposed inside the housing away from the load port and signally connected with the processing unit, the second sensor group comprising at least one third sensor configured to obtain a second height level of the handling portion.

7. The wafer handling apparatus of claim 6, wherein the third sensor is configured to measure a third distance from the handling portion.

8. The wafer handling apparatus of claim 6, wherein the second sensor group further comprises:
at least one fourth sensor configured to obtain a second orientation level of the handling portion.

9. The wafer handling apparatus of claim 8, wherein the fourth sensor comprises at least two second subsidiary sensors, each of the second subsidiary sensors is configured to measure a fourth distance from the handling portion, the processing unit is configured to calculate a second inclination angle of the handling portion according to a second difference between the fourth distances measured.

10. The wafer handling apparatus of claim 9, wherein the second subsidiary sensors are spaced apart from each other and are disposed on a same horizontal level.

11. A method for monitoring a wafer handling apparatus, the method comprising:
providing a first sensor group on a load port mounted on a side of a housing of the wafer handling apparatus, wherein the load port is configured to receive a wafer container, the wafer container is configured to accommodate at least one semiconductor wafer, the housing is configured to accommodate a robotic arm for moving the semiconductor wafer into or out of the wafer container, the robotic arm comprises:
a handling portion configured to hold the semiconductor wafer; and
a moving portion connected with the handling portion and configured to move the handling portion relative to the load port;
obtaining a first height level of the handling portion by the first sensor group;
receiving a first signal from the first sensor group; and
analyzing the first signal and determining if the first height level obtained is within a first predetermined range.

12. The method of claim 11, wherein the first sensor group measures a first vertical distance from the handling portion.

13. The method of claim 11, further comprising:
obtaining a first orientation level of the handling portion by the first sensor group;
receiving a second signal from the first sensor group; and
analyzing the second signal and determining if the first orientation level obtained is within a second predetermined range.

14. The method of claim 13, wherein obtaining the first orientation level comprises:
measuring at least two second vertical distances from the handling portion,
analyzing the second signal comprises:
calculating a first inclination angle of the handling portion according to a first difference between the second vertical distances measured.

15. The method of claim 11, further comprising:
defining a reference zone inside the housing away from the load port;
providing a second sensor group within the reference zone;
moving the handling portion to the reference zone;
obtaining a second height level of the handling portion by the second sensor group;
receiving a third signal from the second sensor group; and
analyzing the third signal and determining if the second height level obtained is within a third predetermined range.

16. The method of claim 15, wherein the second sensor group measures a third vertical distance from the handling portion.

17. The method of claim 15, further comprising:
obtaining a second orientation level of the handling portion by the second sensor group;
receiving a fourth signal from the second sensor group; and
analyzing the fourth signal and determining if the second orientation level obtained is within a fourth predetermined range.

18. The method of claim 17, wherein obtaining the second orientation level comprises:
measuring at least two fourth vertical distances from the handling portion,
analyzing the fourth signal comprises:
calculating a second inclination angle of the handling portion according to a second difference between the fourth vertical distances measured.

19. The method of claim 15, wherein the first sensor group comprises a plurality of first distance sensors, the second sensor group comprises a plurality of second distance sensors, a first position arrangement of the first distance sensors is same as a second position arrangement of the second distance sensors.
